(19) United States
(12) Patent Application Publication
(10) Pub. No.: US 2025/0311261 A1
(43) Pub. Date: Oct. 2, 2025

(54) METHOD FOR SEMICONDUCTOR PROCESSING

(71) Applicant: Tokyo Electron Limited, Tokyo (JP)

(72) Inventors: Hamed Hajibabaeinajafabadi, Albany, NY (US); Toshiki Kanaki, Albany, NY (US); Ivo Otto IV, Albany, NY (US); Subhadeep Kal, Albany, NY (US)

(21) Appl. No.: 18/620,222

(22) Filed: Mar. 28, 2024

(51) Int. Cl. H01L 29/66; H01L 21/02; H01L 21/306; H01L 21/31; H01L 29/06; H01L 29/417; H01L 29/423; H01L 29/775; H01L 29/786

(52) U.S. Cl. CPC H10D 30/014; H01L 21/02532; H01L 21/0262; H01L 21/306; H01L 21/31; H10D 30/43; H10D 30/6735; H10D 30/6757; H10D 62/121; H10D 64/258

(57) ABSTRACT

A method of processing a substrate includes forming a recess by etching a sacrificial layer and forming a blocking layer and an inner spacer in the recess. The sacrificial layer is between a lower nanosheet and an upper nanosheet. The forming the blocking layer includes performing a small molecule treatment with a gas including a leaving group and a remaining group. The method further includes forming a source/drain region and removing the sacrificial layer with an etch process. The source/drain region is adjacent the lower nanosheet, the inner spacer, and the upper nanosheet. The blocking layer protects the source/drain region from etchants.

### TECHNICAL FIELD

The present invention relates generally to semiconductor processing, and, in particular embodiments, to a method of processing a substrate.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices is performed using various deposition and etch techniques such as plasma processes.

The semiconductor industry has traditionally followed Moore's Law, which was initially based on the observation that the number of transistors on a chip doubles approximately every two years, leading to a cadence of shrinking feature sizes (also referred to as “scaling”) along with improvements in performance and reductions in costs. However, as transistor features approached atomic dimensions, maintaining this pace has become increasingly challenging. As a result, the scaling cadence has evolved from a strict focus on gate length reduction to a more complex one incorporating innovations in 3D structures, new materials, and integration methods.

Nanosheet transistors have emerged as a promising advancement in this endeavor, representing a significant evolution from their planar and FinFET predecessors. Nanosheet transistors, characterized by their multiple horizontal sheets, or ‘nanosheets’, of channel material stacked vertically, allow for enhanced control over the current flow and offer the potential for further scaling beyond the limits of conventional FinFET architectures. These devices can effectively maintain excellent electrostatic control over a channel and enable gate-all-around (GAA) configurations, which are imperative for next-generation integrated circuits and high-performance computing applications. Despite the advantages of nanosheet transistors, challenges remain in fabrication techniques, uniformity across large wafers, thermal management, and integration with existing manufacturing processes.

### SUMMARY

In accordance with an embodiment, a method of processing a substrate includes: forming a recess by etching a sacrificial layer, the sacrificial layer being between a lower nanosheet and an upper nanosheet; forming a blocking layer and an inner spacer in the recess, the forming the blocking layer including performing a small molecule treatment with a gas including a leaving group and a remaining group; forming a source/drain region adjacent the lower nanosheet, the inner spacer, and the upper nanosheet; and removing the sacrificial layer with an etch process, the blocking layer protecting the source/drain region from etchants.

In accordance with another embodiment a method of processing a substrate includes: forming a plurality of recesses by recessing sacrificial layers of a layer stack, the layer stack including alternating layers of sacrificial layers and nanosheets; depositing an inner spacer layer over the layer stack, the inner spacer layer filling the recesses; forming a respective inner spacer in each recess of the recesses by etching the inner spacer layer; exposing the substrate to a gas including a small molecule to form a blocking layer on outer sidewalls of the inner spacers, the small molecule including a leaving group and a remaining group; epitaxially growing a source/drain region from exposed tips of the nanosheets, the source/drain region being adjacent the blocking layer; and removing the sacrificial layers with an etching process.

In accordance with yet another embodiment, a method of processing a substrate includes: forming a recess through a layer stack of alternating layers of silicon (Si) layers and silicon-germanium (SiGe) layers, the recess exposing sidewalls of the Si layers and sidewalls of the SiGe layers; forming indents between the Si layers by etching a portion of the SiGe layers selectively to the Si layers; performing a small molecule treatment on exposed surfaces of the indents with a gas including molecules having less than 50 atoms, the small molecule treatment forming a blocking layer; forming respective inner spacers in the indents, the blocking layer covering respective top surfaces, respective bottom surfaces, and respective inner sidewalls of the respective inner spacers; epitaxially growing a source/drain region in the recess, the source/drain region being adjacent the exposed sidewalls of the Si layers and the inner spacers; and removing the SiGe layers with a channel release process.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate cross-sectional views of an example substrate;

FIGS. 2, 3, 4, 5, 6, 7A, 7B, 8, 9, 10, and 11 illustrate cross-sectional views of intermediate stages of a manufacturing process for a semiconductor structure, in accordance with some embodiments;

FIGS. 12, 13, 14A, 14B, 15, 16, and 17 illustrate cross-sectional views of intermediate stages of a manufacturing process for another semiconductor structure, in accordance with some embodiments;

FIG. 18 illustrates an example chemical reaction, in accordance with some embodiments;

FIG. 19 illustrates a flow chart diagram of a method for processing a substrate, in accordance with some embodiments;

FIG. 20 illustrates a flow chart diagram of a method for processing a substrate, in accordance with some embodiments; and

FIG. 21 illustrates a flow chart diagram of a method for processing a substrate, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

This application relates to methods of processing a substrate, and more particularly to methods of reducing or preventing damage to source/drain regions (in other words, to source regions and drain regions) during channel release processes. Generally, fabricating complicated structures for advanced semiconductor devices, for example 3-D devices such as gate-all-around field effect transistors (GAAFETs, also referred to as nanosheet or nanowire FETs) and stacked FETs (also referred to as complementary FETs or CFETs), may require laterally removing materials to selectively expose a portion of the underlying structure. However, it may be challenging to achieve sufficient etch selectivity in certain processes due to the small scale and design complexity of the features to be fabricated.

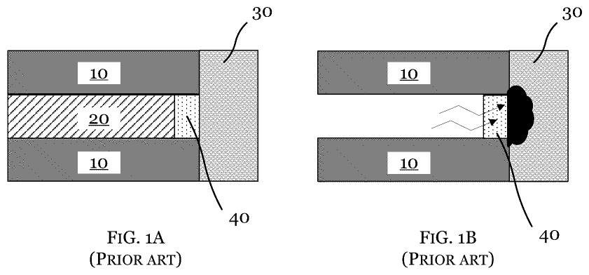

One example of such difficult etch processes is a channel release process for a nanosheet/nanowire p-channel FET (pFET), where the insufficient etch selectivity may cause significant damage to source/drain regions. FIGS. 1A and 1B illustrate cross-sectional views for a p-channel field effect transistor (pFET) with source and drain damage caused by a conventional channel release process. FIG. 1A illustrates the substrate prior to the conventional channel release process, and FIG. 1B illustrates the substrate after the conventional channel release process. Commonly, as illustrated in FIG. 1A, a layer stack of silicon (Si) nanosheets 10 and sacrificial layers 20 is formed to provide multiple Si nanosheet/nanowire channels. Source/drain materials 30 are then epitaxially grown, such as from the tips of the Si nanosheet/nanowire and/or from an adjacent recess in an Si substrate. In typical examples, the source/drain materials 30 comprise boron-doped silicon-germanium (B-doped SiGe) and the sacrificial layers 20 comprise un-doped SiGe. During the channel release process, the sacrificial layers 20 are removed by dry etching. An inner spacer 40 is used to separate the sacrificial layers 20 from the source/drain materials 30 in order to protect the source/drain materials 30 during the channel release process. However, as illustrated in FIG. 1B with arrows, the etch gas used in the conventional channel release process may penetrate the inner spacer 40 to reach and damage the source/drain materials 30. Although the inner spacer 40 may be in principle chemically resistant to the etch gas and able to provide etch selectivity, the penetration of the etch gas may still occur because the inner spacer 40 is typically scaled to a small thickness and made porous to reduce its dielectric constant in order to minimize the parasitic capacitance caused by the inner spacer 40. Therefore, a new solution for an inner spacer that provides better protection for source/drain materials during channel release processes is desirable.

According to one or more embodiments of the present disclosure, a method of reducing or preventing damage to source/drain regions includes a small molecule treatment to reduce or stop diffusion of etchants through inner spacers. In various embodiments, the small molecule treatment is performed with a molecule that is volatile and comprises at least two groups. One groups may be referred to as a leaving group. Upon reaction with groups on a desired surface, the leaving groups are converted to other volatile groups such as, for example, amines, alcohols, thiols, and/or hydrogen halides. Another group may be referred to as a remaining group and comprises a silicon (Si) atom as its central atom bonded with carbon atoms. Upon reaction with the desired surface, the Si center atom of the remaining group forms a bond with surface. As such, a combination of one or more leaving groups, one or more remaining groups, and various other groups can be accordingly mixed to form “small molecules” and be used as a gas for the small molecule treatment.

Various chemicals including N-(Trimethylsilyl)dimethylamine (TMSDMA) and chemicals having similar structures with different amine and/or varying carbon based groups (with less than four carbon atoms) in place of methyl may be used for the small molecule treatment. For example, the small molecules may have less than 50 atoms, or less than 30 atoms. The small molecules may selectively bond with surface —OH and —NH groups on, for example, oxidized Si and SiGe surfaces, dielectric surfaces, and low-k dielectric material of inner spacers to reduce or prevent diffusion of etchant across the inner spacers into the source/drain regions, thereby stopping damage to the source/drain regions. The small molecules bonding with low-k dielectric surfaces may be a self-limiting reaction and provide further protection of dielectric material (e.g., of the inner spacers) during the channel release process. The increased protection of the dielectric material can allow for increasing of over-etch time during the channel release process. This method may be a part of a fabrication process for gate-all-around field effect transistors (GAAFETs) or emerging stacked FETs such as complementary FETs (CFETs), and it may be included with existing process flows with low to no change in process throughput.

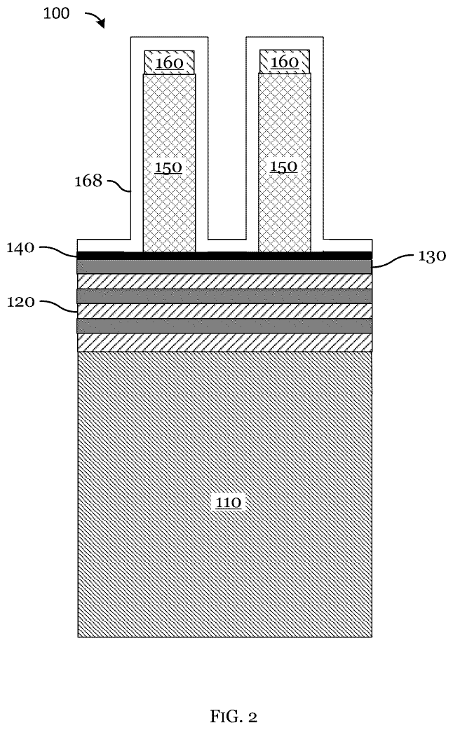

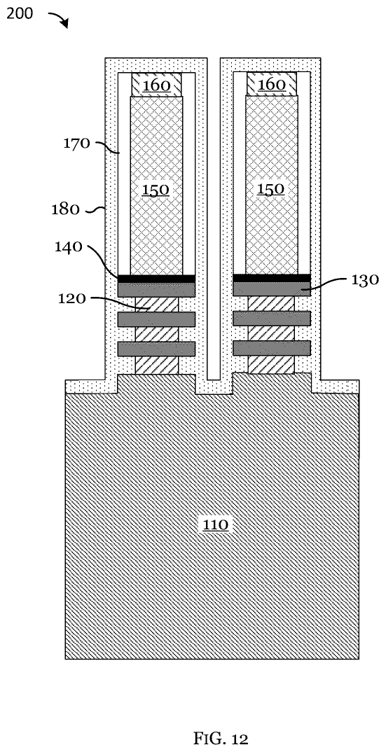

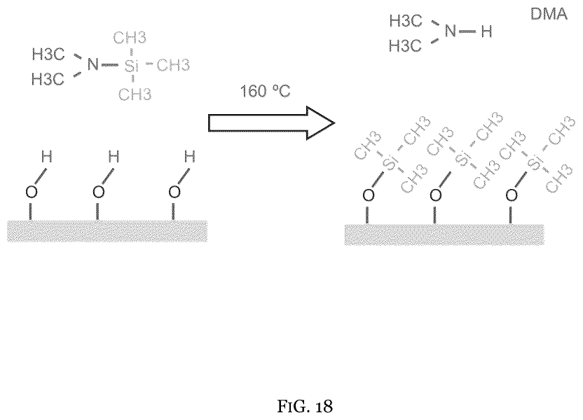

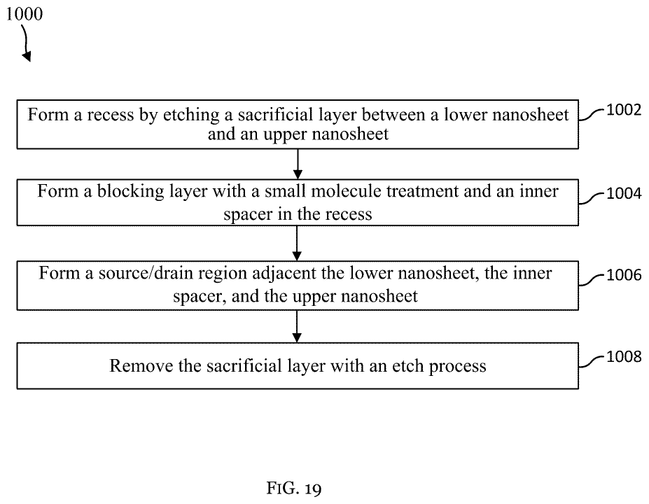

Embodiments of the disclosure are described in the context of the accompanying drawings. An embodiment of a manufacturing process for a semiconductor structure will be described using FIGS. 2, 3, 4, 5, 6, 7A, 7B, 8, 9, 10, and 11. An embodiment of a manufacturing process for another semiconductor structure will be described using FIGS. 12, 13, 14A, 14B, 15, 16, and 17. An example chemical reaction for an embodiment will be described using FIG. 18. Embodiments of methods for processing substrates will be described using FIGS. 19, 20, and 21. Although this disclosure describes embodiments for a channel release process to remove SiGe selectively to a source/drain region of SiGe (e.g., B-doped SiGe) in GAAFET applications, the methods of small molecule treatment for source/drain region channel protection may also be applied in various other applications such as stacked FET applications.

FIGS. 2, 3, 4, 5, 6, 7A, 7B, 8, 9, 10, and 11 illustrate cross-sectional views of a semiconductor device (e.g., a GAAFET device) at intermediate stages of fabrication as an exemplary process flow including a small molecule treatment, in accordance with some embodiments.

FIG. 2 illustrates a cross-sectional view of a semiconductor structure 100 during fabrication. The semiconductor structure 100 may have undergone a number of steps of processing following, for example, a conventional process. As an example, the semiconductor structure 100 comprises a substrate 110 in which various device regions are formed. At this stage, the substrate 110 may include isolation regions such as shallow trench isolation (STI) regions as well as other regions formed therein.

In various embodiments, the substrate 110 comprises a semiconductor substrate. In one or more embodiments, the substrate 110 is a silicon wafer or a silicon-on-insulator (SOI) wafer. In certain embodiments, the substrate 110 comprises a germanium wafer, silicon-germanium wafer, silicon carbide wafer, gallium arsenide wafer, gallium nitride wafer and other compound semiconductors. In other embodiments, the substrate 110 comprises heterogeneous layers such as silicon-germanium on silicon, gallium nitride on silicon, silicon carbon on silicon, as well layers of silicon on a silicon or SOI substrate.

As further illustrated in FIG. 2, a plurality of nanosheets 130 (also referred to as nanosheet layers) are formed over the substrate 110. Specifically, the nanosheets 130 are embedded in a different material. The nanosheets 130 may be spaced apart from each other by one of a plurality of sacrificial layers 120. Thus, a layer stack comprising alternating layers of the sacrificial layers 120 and the nanosheets 130 is over the substrate 110. It should be noted that while three layers of the nanosheets 130 are depicted in FIG. 2, the number of layers is not limited. In various embodiments, at the end of fabrication the nanosheets 130 form channels of a transistor device, while the sacrificial layers 120 will be removed in a later step of fabrication to free up a void space for the formation of a gate dielectric and gate electrode. In various embodiments, the nanosheets 130 have respective thicknesses of a few nanometers to tens of nanometers. For example, in one embodiment the nanosheets 130 have respective thicknesses in a range of 1 nm to 20 nm. In another embodiment, the nanosheets 130 have respective thicknesses in a range of 1 nm to 10 nm. However, the nanosheets 130 may have any suitable thicknesses.

In various embodiments, the sacrificial layers 120 comprise silicon-germanium (SiGe) and the nanosheets 130 comprise silicon (e.g., crystalline silicon). In other embodiments, the sacrificial layers 120 comprise silicon and the nanosheets 130 comprise silicon-germanium. For example, n-type field effect transistors and p-type field effect transistors may be formed with different types of materials. n-FETs may be fabricated with using nanosheets 130 having high electron mobility while p-FETs may be fabricated with using nanosheets 130 having high hole mobility. In certain embodiments, the nanosheets 130 are selected to be a material selected from Groups III-V of the periodic table and the sacrificial layer 120 is selected to be a material from groups II-VI or group IV of the periodic table.

In some embodiments, a layer stack of the nanosheets 130 and the sacrificial layer 120 is formed by deposition processes, for example, epitaxially by a chemical vapor deposition (CVD) method. In various embodiments, each layer of the sacrificial layers 120 and the nanosheets 130 may be a few to several nanometers in thickness. In one embodiment, each layer of the sacrificial layers 120 has a thickness in a range of 5 nm and 20 nm and each layer of the nanosheets 130 has a thickness in a range of 1 nm and 10 nm. However, the sacrificial layers 120 and the nanosheets 130 may have any suitable thicknesses.

As further illustrated in FIG. 2, in some embodiments a dielectric blocking layer 140 is over the alternating layer stack of the nanosheets 130 and the sacrificial layer 120. In various embodiments, the dielectric blocking layer 140 is an oxide layer. The dielectric blocking layer 140 may be formed by one or more suitable deposition processes, such as by a CVD method. The dielectric blocking layer 140 may be used as an etch stop layer, such as for a dummy gate removal process, and may be optional.

In various embodiments, a dummy stack comprising a dummy material is formed over the stack of the nanosheets 130 and the sacrificial layer 120. The dummy stack is patterned to form dummy gates 150. FIG. 2 illustrates a feature of two fins for dummy gates 150 as an example. However, any suitable number of dummy gates 150 may be formed for any suitable number of fins. The dummy gates 150 comprise a suitable material such as polysilicon or amorphous silicon. The dummy gates 150 may be deposited using deposition techniques such as vapor deposition including chemical vapor deposition (CVD), physical vapor deposition (PVD), as well as other plasma processes such as plasma enhanced CVD (PECVD), sputtering, the like, or a combination thereof. In some embodiments, the dummy gates 150 have respective thicknesses of 50 nm to 500 nm.

Still referring to FIG. 2, in some embodiments a hard mask layer is formed before the patterning of the dummy gates 150 to form a hard mask 160. In various embodiments, the hard mask 160 comprises silicon oxide (SiO), silicon dioxide (SiO₂), silicon nitride (SiN), silicon carbonitride (SiCN), silicon oxycarbide (SiOC), silicon oxynitride (SiON), silicon carbide (SiC), amorphous silicon, polycrystalline silicon, titanium nitride (TiN), the like, or a combination thereof. Further, the hard mask 160 may be a stacked hard mask comprising, for example, two or more layers, each of which is formed with a different material. In an example, the first hard mask of the hard mask 160 comprises a metal-based layer such as titanium nitride (TiN), titanium (Ti), tantalum nitride (TaN), tantalum (Ta), tungsten (W) based compounds, ruthenium (Ru) based compounds, or aluminum (Al) based compounds, and the second hard mask of the hard mask 160 comprises a dielectric layer such as silicon oxide (SiO), silicon dioxide (SiO₂), silicon nitride (SiN), silicon carbonitride (SiCN), silicon oxycarbide (SiOC), silicon oxynitride (SiON), silicon carbide (SiC), amorphous silicon, or polycrystalline silicon. The hard mask 160 may be deposited using deposition techniques such as vapor deposition including chemical vapor deposition (CVD), physical vapor deposition (PVD), as well as other plasma processes such as plasma enhanced CVD (PECVD), sputtering, and other processes. In various embodiments, the hard mask 160 has a thickness in a range of 5 nm to 50 nm. In some embodiments, the hard mask 160 is patterned over the layer stack comprising alternating layers of the sacrificial layers 120 and the nanosheets 130, and the dummy gates 150 are not present.

After patterning to form the dummy gate 150 and the hard mask 160, a sidewall spacer layer 168 is deposited over the alternating layer stack of the nanosheets 130 and the sacrificial layer 120. In various embodiments, the optional dielectric blocking layer 140 may be etched prior to depositing the sidewall spacer layer 168. In various embodiments, the sidewall spacer layer 168 comprise a dielectric material comprising an oxide or a nitride. In some embodiments, the sidewall spacer layer 168 comprises silicon-containing dielectric materials such as silicon oxide (SiO), silicon dioxide (SiO₂), silicon oxynitride (SiON), silicon oxycarbonitride (SiOCN), silicon boron carbonitride (SiBCN), the like, or a combination thereof. The sidewall spacer layer 168 may be deposited using deposition techniques such as vapor deposition including chemical vapor deposition (CVD), physical vapor deposition (PVD), as well as other plasma processes such as plasma enhanced CVD (PECVD), atomic layer deposition (ALD), sputtering, and other processes. In various embodiments, the sidewall spacer layer 168 has a thickness in a range of 1 nm to 10 nm. In certain embodiments, the sidewall spacer layer 168 is a stacked layer comprising, for example, two or more layers using two different materials.

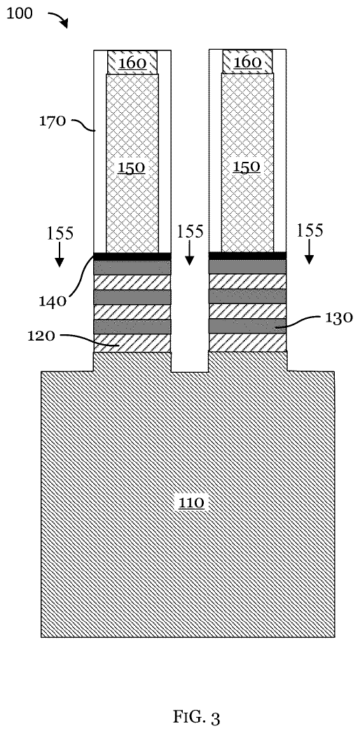

FIG. 3, following from FIG. 2, illustrates the semiconductor structure 100 after anisotropically etching the sidewall spacer layer 168, the alternating layer stack of nanosheets 130 and sacrificial layer 120, and the substrate 110 to form a plurality of vertical recesses 155. An anisotropic etch removes the lateral portions of the sidewall spacer layer 168 so that vertical portions of the sidewall spacer layer 168 remain as sidewall spacers 170 on the sidewalls of the dummy gate 150 and the hard mask 160.

Next, a source/drain fin etch back process may be performed to anisotropically remove portions of the dielectric blocking layer 140 and the alternating layer stack of the nanosheets 130 and the sacrificial layer 120, thereby forming fin features (primarily the channel regions of the transistors) under the dummy gate structures separated by the plurality of vertical recesses 155. In various embodiments, these etch back processes may be performed as a single etch process or alternately as two or more etch processes. In certain embodiments, these etch back process may comprise one or more wet etch processes, plasma etch processes such as reactive ion etch (RIE) processes, or combinations of these or other etch processes. Sidewalls of the nanosheets 130 and the sacrificial layer 120 are exposed by the formation of the vertical recesses 155.

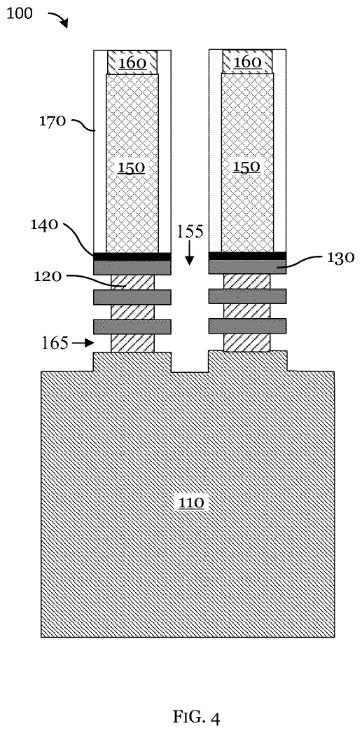

In FIG. 4, a lateral recess etch (cavity etch) is performed on the semiconductor structure 100 to selectively remove a portion of the sacrificial layers 120 relative to the nanosheets 130. In other words, the sacrificial layers 120 are laterally recessed (or etched) to form respective lateral recesses 165 (also referred to as indents) between layers of the nanosheets 130. In various embodiments, the lateral recess etch process comprises one or more isotropic etching process, such as one or more wet etch processes. In other embodiments, the lateral recess etch process includes plasma etch processes such as atomic layer etching processes as well as reactive ion etch (RIE) processes or combinations of these or other etch processes.

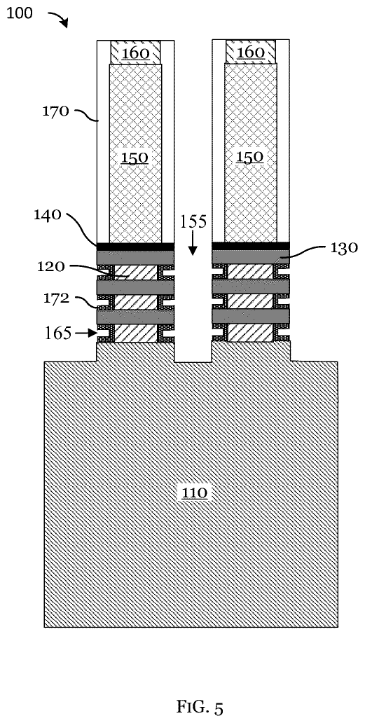

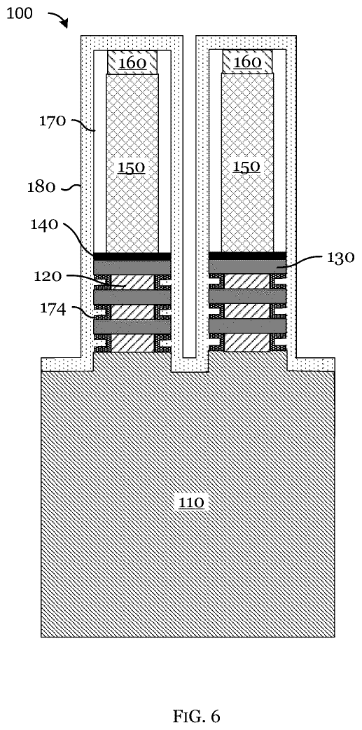

Next, in FIG. 5, a small molecule treatment is performed on the semiconductor structure 100 to modify exposed surfaces of the lateral recesses 165 and form a small molecule layer 172. The small molecule layer 172 (in other words, the result of the surface modification from the small molecule treatment) will subsequently react with deposited material of an inner spacer layer to form a blocking layer (see below, FIG. 6). Although the small molecule layer 172 is illustrated as covering the exposed surfaces of the lateral recesses 165 (including exposed top and bottom surfaces of the nanosheets 130, sidewalls of the sacrificial layers 120, and top surfaces of the substrate 110), the small molecule layer 172 may be formed over any exposed surfaces of the semiconductor structure 100. In some embodiments, the small molecule layer 172 is as thin as a few monolayers or one monolayer of the small molecules from the small molecule treatment. In addition, this self-limiting treatment is advantageous as it can protect the exposed surfaces from growing oxide layers during air exposure.

In various embodiments, the small molecule layer 172 is formed with a small molecule treatment comprising a gas such as N-(Trimethylsilyl)dimethylamine (TMSDMA or (CH₃)₃SiN(CH₃)₂), TMSDEA or N,N-Diethyltrimethylsilylamine, HMDS or Hexamethyldisilazane, Trimethyl(phenylthio) silane, Trimethyl(methylthio) silane, (Ethylthio)trimethylsilane, Methoxytrimethylsilane, Ethoxytrimethylsilane, Isopropoxytrimethylsilane, Bromotrimethylsilane, Chlorotrimethylsilane, Iodotrimethylsilane, the like, or a combination thereof. Molecules of the gas for the small molecule treatment comprise atoms of elements such as silicon, carbon, hydrogen, oxygen, bromine, iodine, chlorine, nitrogen, the like, or a combination thereof. However, any suitable gas may be used. In some embodiments, the gas for the small molecule treatment is provided at a flow rate in a range of 10 sccm to 150 sccm, under a pressure in a range of 0.1 Torr to 8 Torr, at a temperature in a range of 10° C. to 250° C., and for a duration in a range of 10 seconds to 5 minutes. However, any suitable flow rate, pressure, temperature, and process duration may be used.

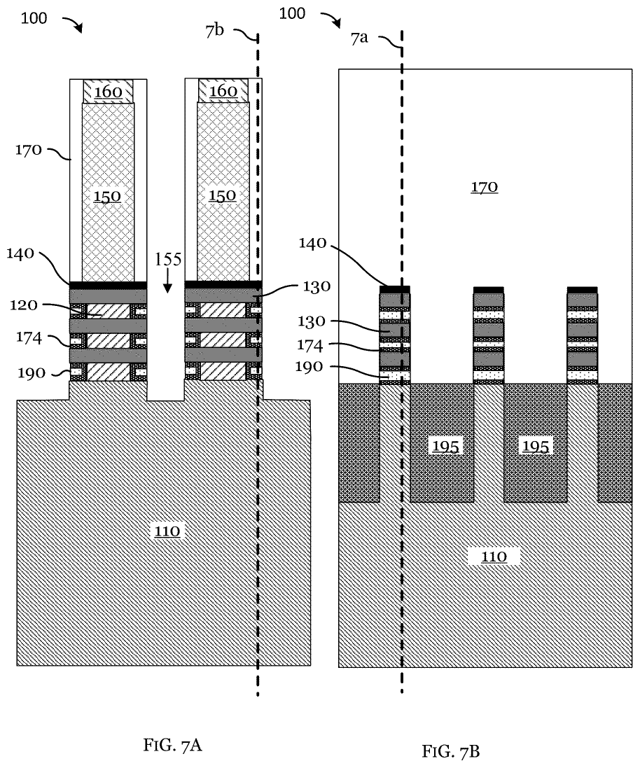

In FIG. 6, following from FIG. 5, an inner spacer layer 180 is formed over the semiconductor structure 100. In this step, the lateral recesses 165 (see above, FIGS. 4-5) are also filled with the material of the inner spacer layer 180. The material of the inner spacer layer 180 may be made porous to reduce its dielectric constant in order to minimize the parasitic capacitance caused by the subsequently formed inner spacers (see below, FIGS. 7A-7B) and thus the material of the inner spacer layer 180 may be a low-k dielectric material.

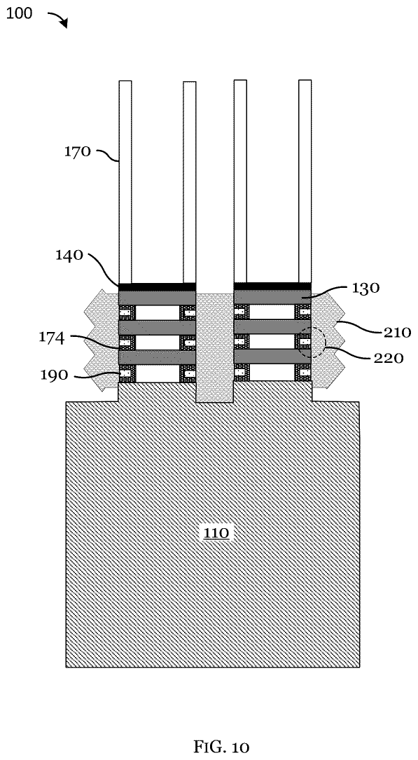

The material of the inner spacer layer 180 reacts with the small molecule layer 172 to form a blocking layer 174 between the inner spacer layer 180 and top and bottom surfaces of the nanosheets 130, sidewalls of the sacrificial layers 120, and top surfaces of the substrate 110. For example, the small molecules of the small molecule layer 172 may selectively bond with surface OH groups from the inner spacer layer 180 to form the blocking layer 174 which may reduce or prevent subsequent diffusion of etchant across the inner spacers into subsequently formed source/drain regions (see below, FIG. 10). The blocking layer 174 may provide further protection of dielectric material (e.g., of the inner spacers) during the channel release process. In some embodiments, the blocking layer 174 comprises a U-shaped profile in a cross-sectional view. Although the blocking layer 174 is illustrated as between the inner spacer layer 180 and top and bottom surfaces of the nanosheets 130, sidewalls of the sacrificial layers 120, and top surfaces of the substrate 110, the blocking layer 174 may be further formed between the inner spacer layer 180 and any other surfaces of the semiconductor structure 100.

In some embodiments, the inner spacer layer 180 comprises silicon-containing dielectric materials such as silicon nitride (SiN), silicon carbonitride (SiCN), silicon oxycarbonitride (SiOCN) and silicon boron carbonitride (SiBCN). The formation of the inner spacer layer 180 may be performed by deposition from a gas phase using, for example, chemical vapor deposition (CVD), plasma-enhanced CVD (PECVD), low-pressure CVD (LPCVD) physical vapor deposition (PVD), atomic layer deposition (ALD), other deposition processes, the like, or a. For a plasma deposition process, a precursor gas mixture can be used including but not limited to silanes, hydrocarbons, fluorocarbons, or nitrogen containing compounds in combination with one or more dilution gases (e.g., argon, nitrogen, etc.) at a variety of pressure, power, flow and temperature conditions.

Next, in FIGS. 7A and 7B, an inner spacer etch back is performed on the semiconductor structure 100 to form inner spacers 190. FIG. 7A illustrates a same cross-sectional view of the semiconductor structure 100 following from FIG. 6, and FIG. 7B illustrates another cross-sectional view of the semiconductor structure 100 perpendicular to the cross-sectional view of FIG. 7A. The inner spacer etch back removes a portion of the inner spacer layer 180 (see above, FIG. 6) to expose tips of the nanosheets 130. The inner spacer etch back may remove the portions of the inner spacer layer 180 over the hard mask 160, the sidewall spacers 170, and the substrate 110. The inner spacer etch back may also remove portions of the blocking layer 174 extending over tips of the nanosheets 130 and over the substrate 110 (if present). Some portions of the inner spacer layer 180 are left between the layers of nanosheets 130 to form inner spacers 190. These remaining portions may provide electrical insulation between the gate region and source/drain region that will be formed at later steps in fabrication. The inner spacers 190 in combination with the blocking layer 174 may reduce or prevent subsequent diffusion of etchant across the inner spacers into source/drain regions (see below, FIG. 10).

In various embodiments, the inner spacer etch back process comprises one or more wet etch processes, plasma etch processes, reactive ion etch (RIE) processes, or combinations of these or other etch processes. In one or more embodiments, the sidewall spacer etch back process comprises an anisotropic etching process, for example, a RIE processes followed optionally by a short isotropic etching process to expose the layers of nanosheets 130.

FIG. 7B illustrates another cross-sectional view of the semiconductor structure 100 along a cross section indicated by the dashed line 7b in FIG. 7A. Conversely, FIG. 7A illustrates the cross-sectional view of the semiconductor structure 100 along a cross section indicated by the dashed line 7a in FIG. 7B. In FIG. 7B, isolation regions such as shallow trench isolation (STI) regions 195 are visible, which may also be present in all of the previous embodiment illustrations (FIGS. 2-6). In various embodiments, the STI regions 195 comprise an oxide such as silicon oxide (SiO) or silicon dioxide (SiO₂). The STI regions 195 serve to electrically isolate adjacent electronic components. With a completion of the inner spacer formation, the tips of the nanosheets 130, the dielectric blocking layer 140, the blocking layer 174, and the inner spacers 190 are exposed and visible in the plurality of vertical recesses 155. However, the sacrificial layers 120 are masked by the inner spacers 190 and the blocking layer 174. Further, in FIG. 7B, the dummy gate 150 visible in FIG. 7A is masked by the sidewall spacer 170. The sidewall spacer 170 is visible after a completion of removing portions of the inner spacer layer 180 (see above, FIG. 6).

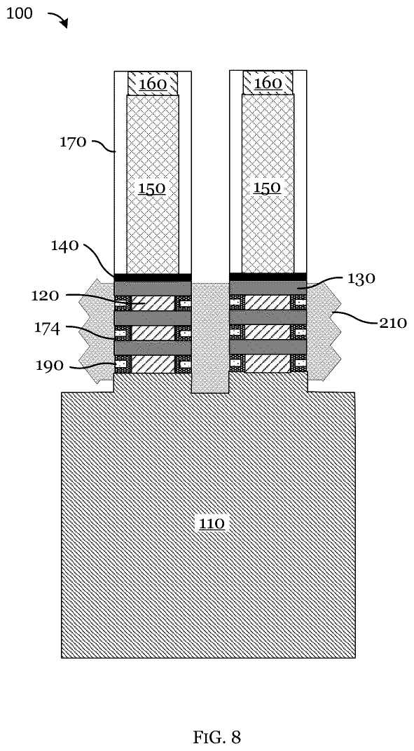

FIG. 8, following from FIG. 7A and illustrating the same cross-sectional view, illustrates a cross-sectional view of the semiconductor structure 100 after source/drain region formation. In various embodiments, source/drain regions 210 are formed with a source/drain material. The source/drain material fills the plurality of vertical recesses 155 (see above, FIG. 7A) and covers the exposed tips of the nanosheets 130. Any remaining unfilled portions of the lateral recesses 165 (see above, FIG. 4) may also be filled by the source/drain material. The formation of the source/drain regions 210 may be performed, for example, by epitaxial growth. In certain embodiments, the source/drain regions 210 formed with an epitaxial growth process comprise a faceted outer surface. In various embodiments, the semiconductor structure 100 is used to fabricate a pFET, and accordingly the source/drain material comprises a p-type semiconductor, for example, boron-doped silicon-germanium (B-doped SiGe). In certain embodiments, the dopant concentration in the source/drain regions 210 is in a range of 1×10²⁰/cm³ to 5×10²⁰/cm³. In one or more embodiments, the B-doped SiGe for the source/drain material has a Ge concentration in a range of 30% and 70%. In various embodiments, the Ge concentration in the source/drain material is higher than that in the sacrificial layer 120.

In certain embodiments, although not specifically illustrated, the semiconductor structure 100 further comprises one or more nFET structures adjacent to the pFET structures illustrated in FIGS. 2-6, 7A, 7B, and 8. For the nFET structures, the semiconductor structure 100 may comprise a similar fin and dummy gate structure where a n-semiconductor (e.g., phosphorous-doped silicon) may be epitaxially grown from the tips of the nanosheets.

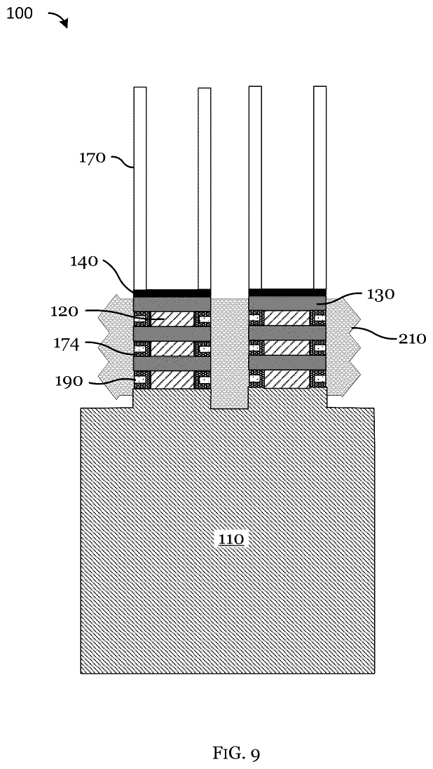

Next, FIG. 9 illustrates a cross-sectional view of the semiconductor structure 100 after a dummy gate removal. After the formation of the source/drain regions 210, the remaining portion of the hard mask 160 and the dummy gates 150 are removed, such as with a dummy gate pull process. In certain embodiments, the dummy gate pull process is performed using a plasma etch process such as a reactive ion etch (RIE) process or the like.

In some embodiments, after the dummy gate pull and prior to a subsequent step of channel release (see below, FIG. 10), an oxide removal process is performed to remove a surface oxide layer that may be present over the sacrificial layers 120. For example, the oxide removal process may be a plasma-less process comprising exposing the semiconductor structure 100 to a process gas (such as a gas comprising, for example, hydrogen fluoride (HF)) in the absence of plasma. In an embodiment, the process gas comprises about 30% HF and 30% NH₃ in a carrier gas (e.g., argon (Ar)) and the process temperature is in a range of 35° C. to 80° C. The oxide removal process may be followed by a thermal treatment comprising heating the semiconductor structure 100 to a temperature in a range of 100° C. to 200° C. under an inert gas flow (such as an argon (Ar) flow).

Following from FIG. 9, FIG. 10 illustrates a cross-sectional view of the semiconductor structure 100 after a channel release process. In some embodiments, the channel release process comprises a fluorocarbon pretreatment step. The fluorocarbon pretreatment comprises exposing the semiconductor structure 100 to a pretreatment gas comprising a fluorocarbon to passivate the material of the source/drain regions 210 (e.g., B-doped SiGe). In various embodiments, the fluorocarbon for the pretreatment gas comprises C₂F₆, C₄F₈, or a compound with a general chemical formula CₓF_{y}. In another embodiment, the fluorocarbon further comprises hydrogen (i.e., hydrofluorocarbon with a general chemical formula CₓH_{y}F_{z}). However, any suitable protection method may be used to protect exposed surfaces of the source/drain regions 210 prior to removing the sacrificial layers 120 with an etch step.

In various embodiments, the etch gas for the etch step of the channel release process comprises an acid such as HF, HBr, HI, water and fluorine-based interhalogens, or a combination thereof. In one or more embodiments, the etch step is performed at a chamber pressure in a range of 10 mTorr to 800 mTorr, at a substrate temperature in a range of −30° C. to 80° C., and/or using Ar and/or N₂ as a carrier gas. In one embodiment, the process time is in a range of 10 seconds and 300 seconds. In one embodiment, the etch step is performed without exposing the semiconductor structure 100 to the fluorocarbon of the pretreatment gas or any other fluorocarbon. In various embodiments, after the etch step, a post-etch thermal treatment is performed by heating the semiconductor structure 100 to a temperature in a range of 100° C. to 250° C. under an inert gas flow (such as a nitrogen (N₂) or argon (Ar) flow).

As indicated by the dotted circle 220 in FIG. 10, the sacrificial layers 120 (e.g., un-doped SiGe) may be removed by the etch process with a reduction or elimination of damage to the source/drain regions 210 (e.g., B-doped SiGe) due to the blocking layer 174 reducing or stopping diffusion of etchant through the inner spacers 190 into the source/drain regions 210. This may overcome the issue described above referring to FIG. 1B. The increased protection provided by the blocking layer 174 may allow for increasing of over-etch time for the etch step during the channel release process.

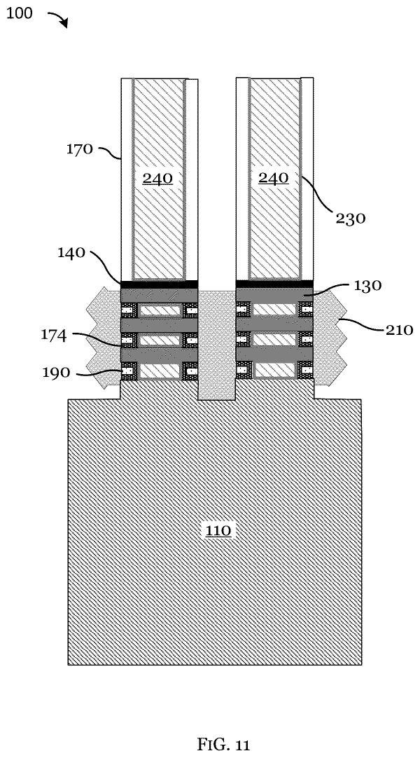

Next, FIG. 11 illustrates a cross-sectional view of the semiconductor structure 100 after a replacement gate formation, such as a high-k metal gate (HKMG). The channel release process (see above, FIG. 10) frees up space previously occupied by the sacrificial layers 120. This created void space may be filled with gate dielectric (e.g., high-k dielectric materials) and gate electrode through the HKMG formation. As an example of a HKMG formation process, first, a high-k dielectric layer 230 is deposited. In some embodiments, the high-k dielectric layer 230 comprises hafnium dioxide (HfO₂), HfₓSi_{y}O₂N_{w}, or the like. The high-k dielectric layer 230 may be deposited using appropriate deposition techniques such as vapor deposition including atomic layer deposition (ALD), chemical vapor deposition (CVD), physical vapor deposition (PVD), as well as other plasma processes such as plasma enhanced CVD (PECVD), sputtering, the like, or a combination thereof. In various embodiments, an optional insulating layer, such as a silicon oxide layer, is formed beneath the high-k dielectric layer 230.

Next, over the high-k dielectric layer 230, a replacement metal gate (RMG) material 240 is deposited to fill the remainder of the void space and complete the HKMG formation. In various embodiments, the RMG material 240 comprises a combination of several layers, including a workfunction metal and a metallic fill material. In some embodiments, the workfunction metal of the RMG material comprises titanium nitride (TiN), tantalum nitride (TaN), metal alloys such as AlC, TiAl and TiAlC, the like, or a combination thereof. Metal deposition is continued till the remaining recesses are filled with excess metallic fill material. In some embodiments, the metallic fill material comprise a low resistivity metal such as tungsten (W), copper (Cu), cobalt (Co), aluminum (Al), the like, or a combination thereof. In some embodiments, the RMG material 240 may be deposited using a highly conformal process such as an atomic layer deposition (ALD) process. However, any suitable process may be used to form the RMG material 240. After the deposition steps, any excess metal may be removed by a planarizing process such as chemical mechanical planarization (CMP). Subsequently, middle-of-line (MOL)/back-end-of-line (BEOL) processes may be performed, such as to form various inter-metal dielectric layers, gate and source/drain conductive contacts, interconnect structures, the like, or a combination thereof, to the GAAFET device(s) of the semiconductor structure 100. Similar processes may be used for other FET devices such as CFETs and are within the scope of the disclosed embodiments.

FIGS. 12, 13, 14A, 14B, 15, 16, and 17 illustrate cross-sectional views of another semiconductor device (e.g., a GAAFET device) at intermediate stages of fabrication as an exemplary process flow including another small molecule treatment, in accordance with some other embodiments.

FIG. 12 illustrates a cross-sectional view of a semiconductor structure 200 after an inner spacer layer 180 is formed over it. The semiconductor structure 200 may be manufactured using similar methods and materials as the semiconductor structure 100 as described above with respect to FIGS. 2-4, and the details are not repeated herein. The inner spacer layer 180 fills lateral recesses between layers of the nanosheets 130, with the absence of the small molecule layer 172 formed in FIG. 5. The inner spacer layer 180 may be formed using similar methods and materials as described above with respect to FIG. 6, and the details are not repeated herein.

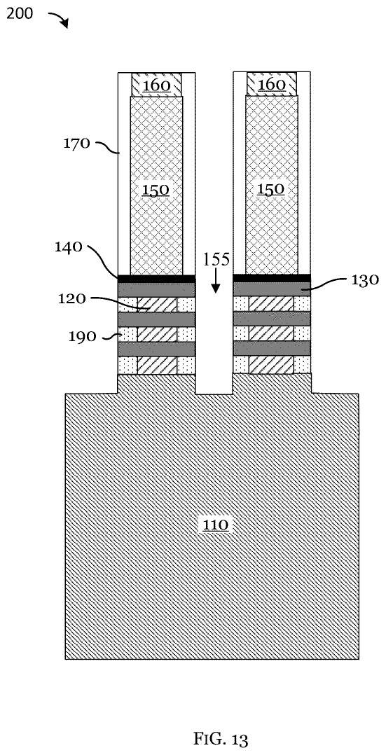

Next, in FIG. 13, an inner spacer etch back is performed on the semiconductor structure 200 to form inner spacers 190. The inner spacer etch back removes a portion of the inner spacer layer 180 (see above, FIG. 12) to expose tips of the nanosheets 130. The inner spacer etch back may remove the portions of the inner spacer layer 180 over the hard mask 160, the sidewall spacers 170, and the substrate 110. Some portions of the inner spacer layer 180 are left between the layers of nanosheets 130 to form inner spacers 190. The inner spacer etch back may be performed using similar methods as described above with respect to FIG. 7A, and the details are not repeated herein.

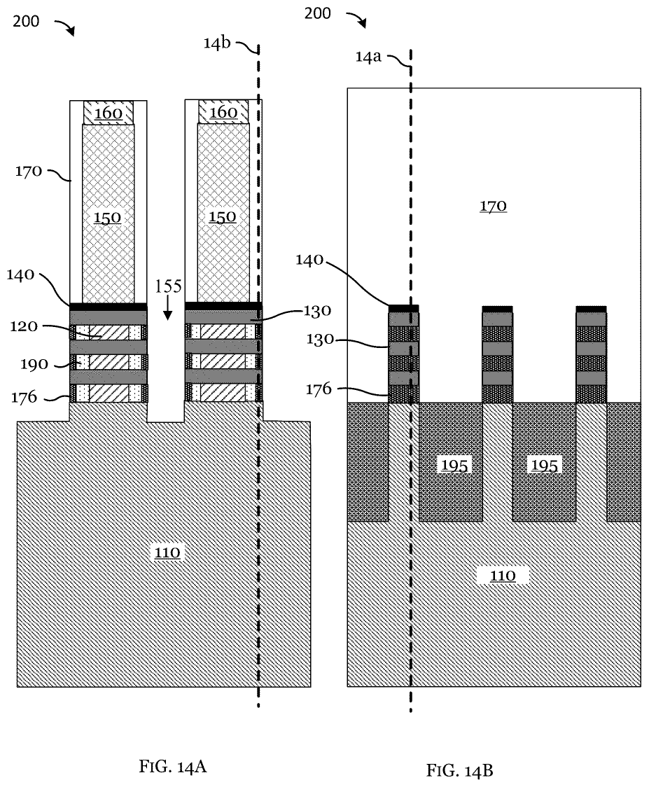

In FIGS. 14A and 14B, a small molecule treatment is performed on the semiconductor structure 200 to form a blocking layer 176 on exposed surfaces (in other words, outer sidewalls) of the inner spacers 190. FIG. 14A illustrates a same cross-sectional view of the semiconductor structure 200 following from FIG. 13, and FIG. 14B illustrates another cross-sectional view of the semiconductor structure 200 perpendicular to the cross-sectional view of FIG. 14A.

In various embodiments, the small molecule treatment comprises a gas such as N-(Trimethylsilyl)dimethylamine (TMSDMA or (CH₃)₃SiN(CH₃)₂), TMSDEA or N,N-Diethyltrimethylsilylamine, HMDS or Hexamethyldisilazane, Trimethyl(phenylthio) silane, Trimethyl(methylthio) silane, (Ethylthio)trimethylsilane, Methoxytrimethylsilane, Ethoxytrimethylsilane, Isopropoxytrimethylsilane, Bromotrimethylsilane, Chlorotrimethylsilane, Iodotrimethylsilane, the like, or a combination thereof. However, any suitable gas may be used. In some embodiments, the gas for the small molecule treatment is provided at a flow rate in a range of 10 sccm to 150 sccm, under a pressure in a range of 0.1 Torr to 8 Torr, at a temperature in a range of 10° C. to 250° C., and for a duration in a range of 10 seconds to 5 minutes. However, any suitable flow rate, pressure, temperature, and process duration may be used.

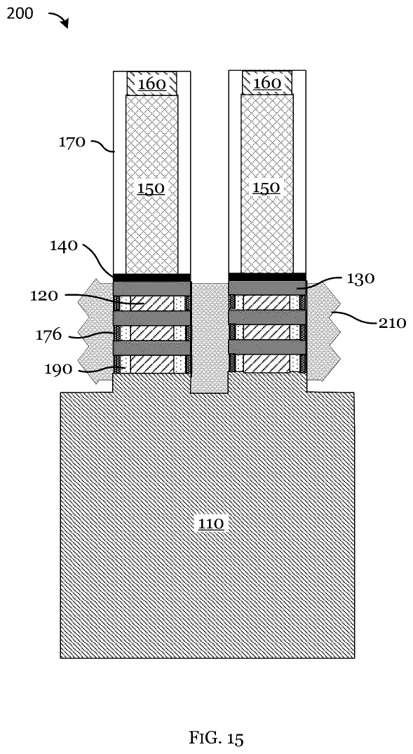

The material of the inner spacers 190 reacts with the small molecule treatment to form a blocking layer 176 over the exposed surfaces of the inner spacers 190 (in other words, over their outer sidewalls). For example, the small molecules (e.g., TMSDMA molecules) may selectively bond with surface OH groups from the inner spacers 190 to form the blocking layer 179 which may reduce or prevent subsequent diffusion of etchant across the inner spacers 190 into subsequently formed source/drain regions (see below, FIG. 15). In some embodiments, the blocking layer 176 comprises a linear profile in a cross-sectional view. The formation of the blocking layer 176 may benefit from damage or roughness of the exposed surfaces of the inner spacers 190 resulting from the prior inner spacer etch back (see above, FIG. 13). This may improve the reaction of the small molecule treatment gas with the exposed surfaces of the inner spacers 190 by, for example, providing more surface OH groups for bonding sites.

FIG. 14B illustrates another cross-sectional view of the semiconductor structure 200 along a cross section indicated by the dashed line 14b in FIG. 14A. Conversely, FIG. 14A illustrates the cross-sectional view of the semiconductor structure 200 along a cross section indicated by the dashed line 14a in FIG. 14B. In FIG. 14B, isolation regions such as shallow trench isolation (STI) regions 195 are visible, which may also be present in all of the previous embodiment illustrations (FIGS. 12-13). The STI regions 195 may be as described above with respect to FIG. 7B, and the details are not repeated herein. The blocking layer 176 is visible between alternating nanosheets 130, as illustrated by FIG. 14B.

FIG. 15, following from FIG. 14A and illustrating the same cross-sectional view, illustrates a cross-sectional view of the semiconductor structure 200 after source/drain region formation. In various embodiments, source/drain regions 210 are formed with a source/drain material. The source/drain material fills the plurality of vertical recesses 155 (see above, FIG. 7A) and covers the exposed tips of the nanosheets 130. Any remaining unfilled portions of the lateral recesses between nanosheets 130 may also be filled by the source/drain material. The formation of the source/drain regions 210 may be performed using similar methods and materials as described above with respect to FIG. 8. In certain embodiments, although not specifically illustrated, the semiconductor structure 200 further comprises one or more nFET structures adjacent to the pFET structures illustrated in FIGS. 12-13, 14A, 14B, and 15. For the nFET structures, the semiconductor structure 200 may comprise a similar fin and dummy gate structure where a n-semiconductor (e.g., phosphorous-doped silicon) may be epitaxially grown from the tips of the nanosheets.

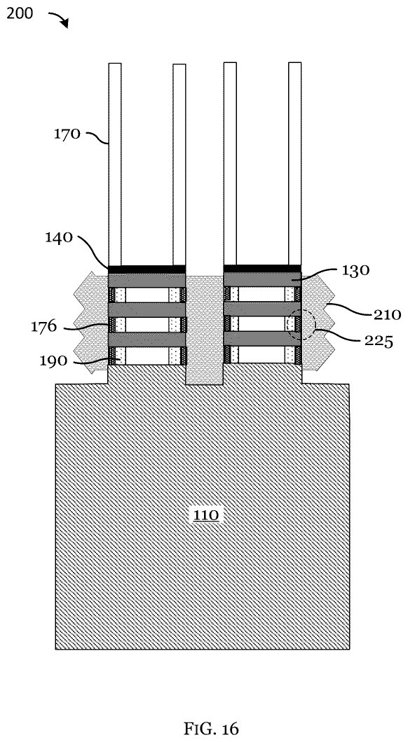

Next, FIG. 16 illustrates a cross-sectional view of the semiconductor structure 200 after a dummy gate removal and a channel release process. After the formation of the source/drain regions 210, the remaining portion of the hard mask 160 and the dummy gates 150 are removed, such as with a dummy gate pull process. The remaining portion of the hard mask 160 and the dummy gates 150 may be removed using similar methods as described above with respect to FIG. 9, and the details are not repeated herein.

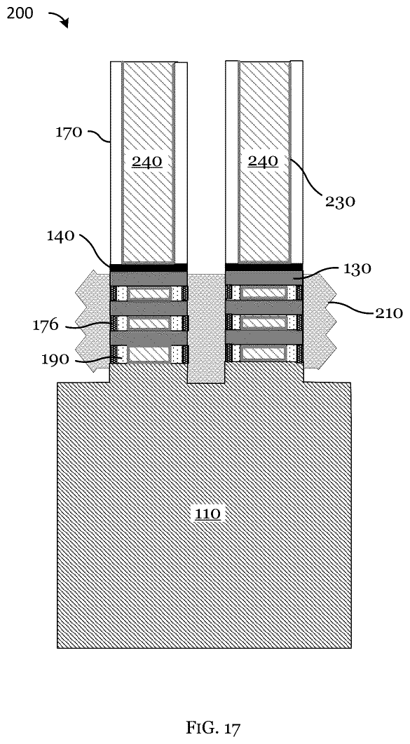

Next, a channel release process is performed. The sacrificial layers 120 may be removed by a channel release process using similar methods (e.g., a plasma-less etch process) as described above with respect to FIG. 10, and the details are not repeated herein. As indicated by the dotted circle 225 in FIG. 17, the sacrificial layers 120 (e.g., un-doped SiGe) may be removed by the etch process with a reduction or elimination of damage to the source/drain regions 210 (e.g., B-doped SiGe) due to the blocking layer 176 reducing or stopping diffusion of etchant through the inner spacers 190 and into the source/drain regions 210. This may overcome the issue described above referring to FIG. 1B. The increased protection provided by the blocking layer 176 may allow for increasing of over-etch time for the etch step during the channel release process.

Next, FIG. 17 illustrates a cross-sectional view of the semiconductor structure 200 after a replacement gate formation, such as a high-k metal gate (HKMG). A high-k dielectric layer 230 and a replacement metal gate (RMG) material 240 may be formed using similar methods and materials as described above with respect to FIG. 11, and the details are not repeated herein. Subsequently, middle-of-line (MOL)/back-end-of-line (BEOL) processes may be performed, such as to form various inter-metal dielectric layers, gate and source/drain conductive contacts, interconnect structures, the like, or a combination thereof, to the GAAFET device(s) of the semiconductor structure 200. Similar processes may be used for other FET devices such as CFETs and are within the scope of the disclosed embodiments.

FIG. 18 illustrates an example chemical reaction of N-(Trimethylsilyl)dimethylamine (TMSDMA) molecules with a surface having OH groups, in accordance with some embodiments. This reaction may occur when a small molecule treatment with TMSDMA is applied to a low-k dielectric surface (e.g., an exposed surface of an inner spacer 190) such as during a formation of a blocking layer 176, as described above with respect to FIG. 14A. At a reaction temperature of, for example, around 160° C., the Si(CH₃)₃ groups (in other words, examples of leaving groups) replace the hydrogen atoms in the surface OH groups, while the hydrogen atoms bond with the remaining dimethylamine (DMA) (in other words, examples of remaining groups). As such, the silicon atoms of the small molecule treatment gas may replace hydrogen atoms of the targeted surface. Simulated and experimental data suggest that TMSDMA reaction with crystalline silicon of the nanosheets or SiGe of the source/drain regions is either thermodynamically or kinematically hindered. As such, reaction of the TMSDMA with low-k silicon oxide of the inner spacer exposed surfaces is favored and so the small molecule treatment may be self-limiting. X-ray photoelectron spectroscopy (XPS) data further suggests that higher carbon (C) is present after TMSDMA treatment of thermal oxide and silicon nitride surfaces, which may indicate a reaction with the TMSDMA.

FIG. 19 illustrates a flow chart diagram of a method 1000 for processing a substrate, in accordance with some embodiments. In step 1002, a recess is formed by etching a sacrificial layer, as described above with respect to FIG. 4. The sacrificial layer is between a lower nanosheet and an upper nanosheet. In step 1004, a blocking layer and an inner spacer are formed in the recess, as described above with respect to FIGS. 5, 6, and 7A, or FIGS. 12, 13, and 14A. The forming the blocking layer comprises performing a small molecule treatment with a gas comprising a leaving group and a remaining group.

In step 1006, a source/drain region is formed adjacent the lower nanosheet, the inner spacer, and the upper nanosheet, as described above with respect to FIG. 8 or FIG. 15. In step 1008, the sacrificial layer is removed with an etch process, as described above with respect to FIG. 10 or FIG. 16. The blocking layer protects the source/drain region from etchants.

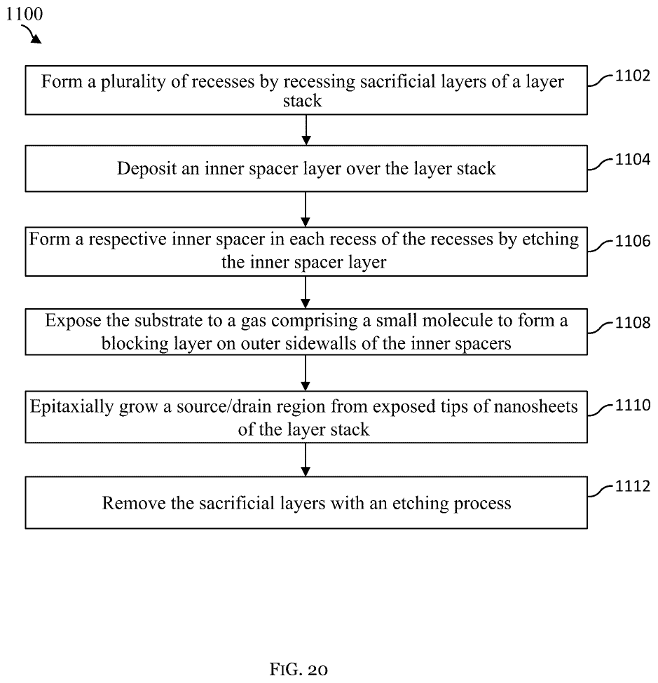

FIG. 20 illustrates a flow chart diagram of a method 1100 for processing a substrate, in accordance with some embodiments. In step 1102, a plurality of recesses are formed by recessing sacrificial layers of a layer stack, as described above with respect to FIG. 4. The layer stack comprises alternating layers of sacrificial layers and nanosheets. In step 1104, an inner spacer layer is deposited over the layer stack, as described above with respect to FIG. 12. The inner spacer layer fills the recesses.

In step 1106, a respective inner spacer is formed in each recess of the recesses by etching the inner spacer layer, as described above with respect to FIG. 13. In step 1108, the substrate is exposed to a gas comprising a small molecule to form a blocking layer on outer sidewalls of the inner spacers, as described above with respect to FIG. 14A. The small molecule comprises a leaving group and a remaining group.

In step 1110, a source/drain region is epitaxially grown from exposed tips of the nanosheets, as described above with respect to FIG. 15. The source/drain region is adjacent the blocking layer. In step 1112, the sacrificial layers with an etching process, as described above with respect to FIG. 16.

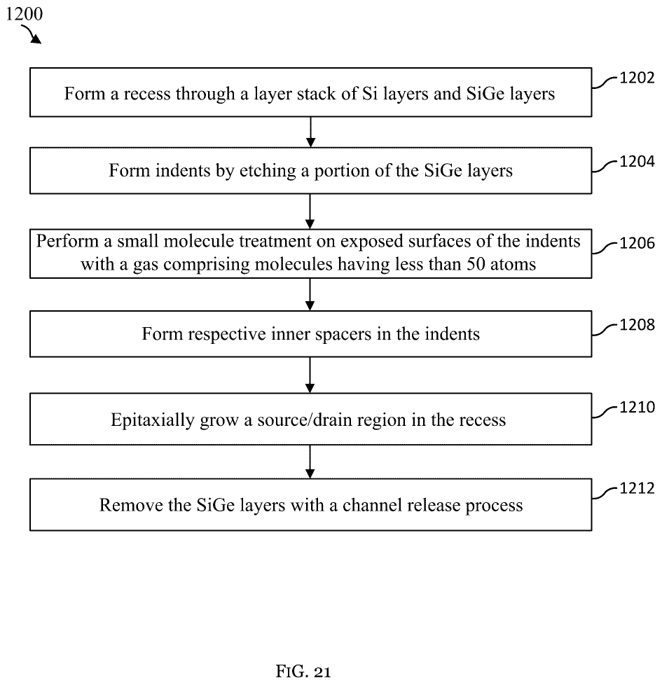

FIG. 21 illustrates a flow chart diagram of a method 1200 for processing a substrate, in accordance with some embodiments. In step 1202, a recess is formed through a layer stack of alternating layers of silicon (Si) layers and silicon-germanium (SiGe) layers, as described above with respect to FIG. 3. The recess exposes sidewalls of the Si layers and sidewalls of the SiGe layers. In step 1204, indents are formed between the Si layers by etching a portion of the SiGe layers selectively to the Si layers, as described above with respect to FIG. 4.

In step 1206, a small molecule treatment is performed on exposed surfaces of the indents with a gas comprising molecules having less than 50 atoms, as described above with respect to FIG. 5. The small molecule treatment forms a blocking layer. In step 1208, respective inner spacers are formed in the indents, as described above with respect to FIGS. 6 and 7A. The blocking layer covers respective top surfaces, respective bottom surfaces, and respective inner sidewalls of the respective inner spacers.

In step 1210, a source/drain region is epitaxially grown in the recess, as described above with respect to FIG. 8. The source/drain region is adjacent the exposed sidewalls of the Si layers and the inner spacers. In step 1212, the SiGe layers are removed with a channel release process, as described above with respect to FIG. 10.

Example embodiments of the disclosure are summarized here. Other embodiments can also be understood from the entirety of the specification as well as the claims filed herein.

Example 1. A method of processing a substrate, the method including: forming a recess by etching a sacrificial layer, the sacrificial layer being between a lower nanosheet and an upper nanosheet; forming a blocking layer and an inner spacer in the recess, the forming the blocking layer including performing a small molecule treatment with a gas including a leaving group and a remaining group; forming a source/drain region adjacent the lower nanosheet, the inner spacer, and the upper nanosheet; and removing the sacrificial layer with an etch process, the blocking layer protecting the source/drain region from etchants.

Example 2. The method of example 1, where the small molecule treatment includes N-(Trimethylsilyl)dimethylamine.

Example 3. The method of one of examples 1 or 2, where the small molecule treatment includes N,N-Diethyltrimethylsilylamine (TMSDEA), Hexamethyldisilazane (HMDS), Trimethyl(phenylthio) silane, Trimethyl(methylthio) silane, (Ethylthio)trimethylsilane, Methoxytrimethylsilane, Ethoxytrimethylsilane, Isopropoxytrimethylsilane, Bromotrimethylsilane, Chlorotrimethylsilane, or Iodotrimethylsilane.

Example 4. The method of one of examples 1 to 3, where molecules from the gas including the leaving group and the remaining group have less than 50 atoms.

Example 5. The method of one of examples 1 to 4, where the sacrificial layer and the source/drain region include silicon-germanium (SiGe), and where the lower nanosheet and the upper nanosheet include silicon (Si).

Example 6. The method of one of examples 1 to 5, where the inner spacer is formed over the blocking layer.

Example 7. The method of example 6, where the blocking layer includes a U-shaped profile in a cross-sectional view covering a top surface, a bottom surface, and an inner sidewall of the inner spacer.

Example 8. The method of one of examples 1 to 5, where the blocking layer is formed over the inner spacer.

Example 9. The method of example 8, where the blocking layer includes a linear profile in a cross-sectional view, the blocking layer covering an outer sidewall of the inner spacer.

Example 10. A method of processing a substrate, the method including: forming a plurality of recesses by recessing sacrificial layers of a layer stack, the layer stack including alternating layers of sacrificial layers and nanosheets; depositing an inner spacer layer over the layer stack, the inner spacer layer filling the recesses; forming a respective inner spacer in each recess of the recesses by etching the inner spacer layer; exposing the substrate to a gas including a small molecule to form a blocking layer on outer sidewalls of the inner spacers, the small molecule including a leaving group and a remaining group; epitaxially growing a source/drain region from exposed tips of the nanosheets, the source/drain region being adjacent the blocking layer; and removing the sacrificial layers with an etching process.

Example 11. The method of example 10, where the small molecule includes N-(Trimethylsilyl) dimethylamine.

Example 12. The method of one of examples 10 or 11, where the small molecule includes N,N-Diethyltrimethylsilylamine (TMSDEA), Hexamethyldisilazane (HMDS), Trimethyl(phenylthio) silane, Trimethyl(methylthio) silane, (Ethylthio)trimethylsilane, Methoxytrimethylsilane, Ethoxytrimethylsilane, Isopropoxytrimethylsilane, Bromotrimethylsilane, Chlorotrimethylsilane, or Iodotrimethylsilane.

Example 13. The method of one of examples 10 to 12, where the small molecule has less than 30 atoms.

Example 14. The method of one of examples 10 to 13, where the sacrificial layers and the source/drain region include silicon-germanium (SiGe) and the nanosheets include crystalline silicon.

Example 15. The method of one of examples 10 to 14, where the blocking layer includes a linear profile in a cross-sectional view.

Example 16. A method of processing a substrate, the method including: forming a recess through a layer stack of alternating layers of silicon (Si) layers and silicon-germanium (SiGe) layers, the recess exposing sidewalls of the Si layers and sidewalls of the SiGe layers; forming indents between the Si layers by etching a portion of the SiGe layers selectively to the Si layers; performing a small molecule treatment on exposed surfaces of the indents with a gas including molecules having less than 50 atoms, the small molecule treatment forming a blocking layer; forming respective inner spacers in the indents, the blocking layer covering respective top surfaces, respective bottom surfaces, and respective inner sidewalls of the respective inner spacers; epitaxially growing a source/drain region in the recess, the source/drain region being adjacent the exposed sidewalls of the Si layers and the inner spacers; and removing the SiGe layers with a channel release process.

Example 17. The method of example 16, where the small molecule treatment includes a self-limiting reaction of N-(Trimethylsilyl) dimethylamine with —OH groups of the exposed surfaces of the indents.

Example 18. The method of one of examples 16 or 17, where the blocking layer includes a U-shaped profile in a cross-sectional view.

Example 19. The method of one of examples 16 to 18, where the source/drain region includes boron-doped SiGe.

Example 20. The method of one of examples 16 to 19, where the inner spacers include silicon nitride, silicon carbonitride (SiCN), silicon oxycarbonitride (SiOCN), or silicon boron carbonitride (SiBCN).

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
forming a recess by etching a sacrificial layer, the sacrificial layer being between a lower nanosheet and an upper nanosheet;
forming a blocking layer and an inner spacer in the recess, the forming the blocking layer comprising performing a small molecule treatment with a gas comprising a leaving group and a remaining group;
forming a source/drain region adjacent the lower nanosheet, the inner spacer, and the upper nanosheet; and
removing the sacrificial layer with an etch process, the blocking layer protecting the source/drain region from etchants.

2. The method of claim 1, wherein the small molecule treatment comprises N-(Trimethylsilyl) dimethylamine.

3. The method of claim 1, wherein the small molecule treatment comprises N,N-Diethyltrimethylsilylamine (TMSDEA), Hexamethyldisilazane (HMDS), Trimethyl(phenylthio) silane, Trimethyl(methylthio) silane, (Ethylthio)trimethylsilane, Methoxytrimethylsilane, Ethoxytrimethylsilane, Isopropoxytrimethylsilane, Bromotrimethylsilane, Chlorotrimethylsilane, or Iodotrimethylsilane.

4. The method of claim 1, wherein molecules from the gas comprising the leaving group and the remaining group have less than 50 atoms.

5. The method of claim 1, wherein the sacrificial layer and the source/drain region comprise silicon-germanium (SiGe), and wherein the lower nanosheet and the upper nanosheet comprise silicon (Si).

6. The method of claim 1, wherein the inner spacer is formed over the blocking layer.

7. The method of claim 6, wherein the blocking layer comprises a U-shaped profile in a cross-sectional view covering a top surface, a bottom surface, and an inner sidewall of the inner spacer.

8. The method of claim 1, wherein the blocking layer is formed over the inner spacer.

9. The method of claim 8, wherein the blocking layer comprises a linear profile in a cross-sectional view, the blocking layer covering an outer sidewall of the inner spacer.

10. A method of processing a substrate, the method comprising:
forming a plurality of recesses by recessing sacrificial layers of a layer stack, the layer stack comprising alternating layers of sacrificial layers and nanosheets;
depositing an inner spacer layer over the layer stack, the inner spacer layer filling the recesses;
forming a respective inner spacer in each recess of the recesses by etching the inner spacer layer;
exposing the substrate to a gas comprising a small molecule to form a blocking layer on outer sidewalls of the inner spacers, the small molecule comprising a leaving group and a remaining group;
epitaxially growing a source/drain region from exposed tips of the nanosheets, the source/drain region being adjacent the blocking layer; and
removing the sacrificial layers with an etching process.

11. The method of claim 10, wherein the small molecule comprises N-(Trimethylsilyl) dimethylamine.

12. The method of claim 10, wherein the small molecule comprises N,N-Diethyltrimethylsilylamine (TMSDEA), Hexamethyldisilazane (HMDS), Trimethyl(phenylthio) silane, Trimethyl(methylthio) silane, (Ethylthio)trimethylsilane, Methoxytrimethylsilane, Ethoxytrimethylsilane, Isopropoxytrimethylsilane, Bromotrimethylsilane, Chlorotrimethylsilane, or Iodotrimethylsilane.

13. The method of claim 10, wherein the small molecule has less than 30 atoms.

14. The method of claim 10, wherein the sacrificial layers and the source/drain region comprise silicon-germanium (SiGe) and the nanosheets comprise crystalline silicon.

15. The method of claim 10, wherein the blocking layer comprises a linear profile in a cross-sectional view.

16. A method of processing a substrate, the method comprising:
forming a recess through a layer stack of alternating layers of silicon (Si) layers and silicon-germanium (SiGe) layers, the recess exposing sidewalls of the Si layers and sidewalls of the SiGe layers;
forming indents between the Si layers by etching a portion of the SiGe layers selectively to the Si layers;
performing a small molecule treatment on exposed surfaces of the indents with a gas comprising molecules having less than 50 atoms, the small molecule treatment forming a blocking layer;
forming respective inner spacers in the indents, the blocking layer covering respective top surfaces, respective bottom surfaces, and respective inner sidewalls of the respective inner spacers;
epitaxially growing a source/drain region in the recess, the source/drain region being adjacent the exposed sidewalls of the Si layers and the inner spacers; and
removing the SiGe layers with a channel release process.

17. The method of claim 16, wherein the small molecule treatment comprises a self-limiting reaction of N-(Trimethylsilyl) dimethylamine with —OH groups of the exposed surfaces of the indents.

18. The method of claim 16, wherein the blocking layer comprises a U-shaped profile in a cross-sectional view.

19. The method of claim 16, wherein the source/drain region comprises boron-doped SiGe.

20. The method of claim 16, wherein the inner spacers comprise silicon nitride, silicon carbonitride (SiCN), silicon oxycarbonitride (SiOCN), or silicon boron carbonitride (SiBCN).
